(19) United States
(12) Patent Application Publication
(10) Pub. No.: US 2006/0226874 A1
(43) Pub. Date: Oct. 12, 2006

(54) Interface circuit including voltage level shifter

(76) Inventor: Min-su Kim, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/391,292

(22) Filed: Mar. 29, 2006

(30) Foreign Application Priority Data
Apr. 6, 2005 (KR) 10-2005-0028535

(51) Int. Cl. H03K 19/0175

(52) U.S. Cl. 326/81

(57) ABSTRACT

An interface circuit includes a level shifter which shifts a voltage level of a first signal and a second signal from a first voltage level to a second voltage level. A first PMOS transistor is gated to an output of the level shifter and connected between a first node and a supply voltage of the second voltage level. A second PMOS transistor is gated to receive the second signal and connected between the first node and an output terminal. A first NMOS transistor is gated to receive the second signal and connected between the output terminal and a ground voltage.

### BACKGROUND OF THE INVENTION

1. Field of the Invention

The present invention generally relates to integrated circuits, and more particularly, the present invention relates to interface circuits which include a voltage level shifter.

A claim of priority is made to Korean Patent Application No. 10-2005-0028535, filed on Apr. 6, 2005, in the Korean Intellectual Property Office, the disclosure of which is incorporated herein in its entirety by reference.

2. Description of the Related Art

With the increased functionality of high-performance mobile devices, it has become increasingly necessary to design and fabricate low-power semiconductor circuits to be utilized in such devices. As a result, various energy saving techniques have been developed in an effort to extend the duration that the devices remain operable under battery power. One such energy saving technique involves dividing internal components of a mobile device into several circuit blocks which are driven at different voltages.

Generally, mobile devices may be configured such that relatively high voltages are applied to circuit blocks having high-performance requirements, and relatively low voltages are applied to remaining circuit blocks of the devices. However, since different voltages are applied to the respective circuit blocks, leakage current causing functional errors may occur between adjacent circuit blocks. As such, in an effort to overcome this problem, a level shifter implemented as an interface circuit for varying voltage levels may be installed between the respective circuit blocks.

However, as explained herein below, the use of a level shifter in a circuit block interface circuit can cause operational time delays. This can result in the interface circuit becoming a critical path of the mobile device circuitry.

A conventional interface circuit will now be described with reference to the circuit diagram of FIG. 1. The interface circuit is used to convert an input signal of a first voltage level VDD1 to an output signal of a second voltage level VDD2. The first voltage level VDD1 may be higher or lower than the second voltage level VDD2.

As shown, the conventional interface circuit 10 includes a level shifter 10a and an inverter 10b. More specifically, the circuit 10 includes an input terminal 11 which receives an input signal, an output terminal 13 which outputs an output signal, first through fourth PMOS transistors P1-P4, and first through fourth NMOS transistors N1-N4.

The first PMOS transistor P1 is connected between a first supply voltage VDD1 and a first node ND1, and is gated to the input terminal 11. The first NMOS transistor N1 is connected between the first node ND1 and a ground voltage VSS, and is also gated to the input terminal 11.

The second PMOS transistor P2 is connected between a second supply voltage VDD2 and a second node ND2, and is gated to a third node ND3. The second NMOS transistor N2 is connected between a second node ND2 and the ground voltage VSS, and is gated to the input terminal 11.

The third PMOS transistor P3 is connected between the second supply voltage VDD2 and the third node ND3, and is gated to the second node ND2. The third NMOS transistor N3 is connected between the third node ND3 and the ground voltage VSS, and is gated to the first node ND1.

The fourth PMOS transistor P4 is connected between the second supply voltage VDD2 and the output terminal 13, and is gated to the third node ND3. The fourth NMOS transistor N4 is connected between the output terminal 13 and the ground voltage VSS, and is gated to the third node ND3.

The interface circuit 10 shown in FIG. 1 is an inverter-type level shifter, i.e, the input is logically inverted relative to the output. A buffer-type level shifter can be constructed by adding an inverter at the input terminal 11 or at the output terminal 13 of interface circuit 10.

Now, the operation of the conventional interface circuit 10 will now be described.

Still referring to FIG. 1, if a logic ‘HIGH’ signal of the first voltage VDD1 is applied to the input terminal 11, the first PMOS transistor P1 is turned off and the first NMOS transistor N1 is turned on, so that the output of the first node ND1 goes LOW. Also, the second NMOS transistor N2 is turned on so that the output of the second node ND2 goes LOW, and accordingly the third PMOS transistor P3 is turned on and the third NMOS transistor N3 is turned off so that the output of the third node ND3 goes HIGH. At this time, the second PMOS transistor P2 is turned off, so as to fix the output of the second node ND2 to LOW. Since the output of the third node ND3 is HIGH, the fourth PMOS transistor P4 is turned off and the fourth NMOS transistor N4 is turned on, so that the output of the output terminal 13 goes LOW.

The path of signal propagation from the input terminal 11 to the output terminal 13 includes a maximum of three transistors stages. That is, a signal applied to the input terminal 11 is transmitted to the output terminal 13 via a first stage of the first PMOS transistor P1 and the first NMOS transistor N1, a second stage of the third NMOS transistor N3, and a third stage of the fourth PMOS transistor P4 and the fourth NMOS transistor N4. Alternately, the signal is transmitted to the output terminal 13 via a first stage of the second NMOS transistor N2, a second stage of the third PMOS transistor P3, and a third stage of the fourth PMOS transistor P4 and the fourth NMOS transistor N4. If a buffer-type level shifter is constructed by further including an inverter, the path of signal propagation from the input terminal 11 to the output terminal 13 will include a maximum of four transistors stages.

If a logic ‘LOW’ signal is applied to the input terminal 11, the first PMOS transistor P1 is turned on and the first NMOS transistor N1 is turned off, so that the output of the first node ND1 goes HIGH. Accordingly, the third NMOS transistor N3 is turned on and the output of the third node ND3 goes LOW. Thus, the second PMOS transistor P2 is turned on and the second NMOS transistor N2 is turned off, so that the output of the second node ND2 goes HIGH. At this time, the third PMOS transistor P3 is turned off, so as to fix the output of the third node ND3 to LOW. Since the output of the third node ND3 is LOW, the fourth PMOS transistor P4 is turned on and the fourth NMOS transistor N4 is turned off, so that the output of the output terminal 13 goes HIGH. In this case, a logic ‘HIGH’ signal output from the output terminal 13 swings to the second supply voltage VDD2, and the voltage level is thereby shifted.

Again, the path of signal propagation from the input terminal 11 to the output terminal 13 includes a maximum of three transistors stages. That is, a signal applied to the input terminal 11 is transmitted to the output terminal 13 via a first stage of the first PMOS transistor P1 and the first NMOS transistor N1, a second stage of the third NMOS transistor N3, and a third stage of the fourth PMOS transistor P4 and the fourth NMOS transistor N4. Alternately, the signal is transmitted to the output terminal 13 via a first stage of the second NMOS transistor N2, a second stage of the third PMOS transistor P3, and a third stage of the fourth PMOS transistor P4 and the fourth NMOS transistor N4. If a buffer-type level shifter is constructed by further including an inverter, the path of signal propagation from the input terminal 11 to the output terminal 13 will include a maximum of four transistor stages.

In the conventional level shifter such as that described above, the path of signal propagation from an input terminal to an output terminal includes at least three transistor stages. The resultant time delay adversely influences the overall circuit performance. Particularly in case of a buffer-type level shifter which transmits signals via four transistor stages, the time delay can be a critical factor in achieving the necessary circuit performance.

### SUMMARY OF THE INVENTION

According to an aspect of the present invention, an interface circuit is provided which includes a level shifter which shifts a voltage level of a first signal and a second signal from a first voltage level to a second voltage level, a first PMOS transistor gated to an output of the level shifter and connected between a first node and a supply voltage of the second voltage level, a second PMOS transistor gated to receive a second signal and connected between the first node and an output terminal, and a first NMOS transistor gated to receive the second signal and connected between the output terminal and a ground voltage.

According to another aspect of the present invention, an interface circuit is provided which includes an input terminal which receives an input signal, an output terminal which outputs an output signal, a first PMOS transistor gated to the input terminal and connected between a first node and a first supply voltage having a first voltage level, a first NMOS transistor gated to the input terminal and connected between the first node and a ground voltage, a second PMOS transistor gated to a third node and connected between a second node and a second supply voltage having a second voltage level, a second NMOS transistor gated to the input terminal and connected between the second node and the ground voltage, a third PMOS transistor gated to the second node and connected between the second supply voltage and a third node, a third NMOS transistor gated to the first node and connected between the third node and the ground voltage, a fourth PMOS transistor gated to the second node and connected between the second supply voltage and a fourth node, a fifth PMOS transistor gated to the first node and connected between the fourth node and the output terminal, and a fourth NMOS transistor gated to the first node and connected between the output terminal and the ground voltage.

According to another aspect of the present invention, an interface circuit is provided which includes an input terminal which receives an input signal, an output terminal which receives an output signal, a first PMOS transistor gated to the input terminal and connected between a first node and a first supply voltage having a first supply level, a first NMOS transistor gated to the input terminal and connected between the first node and a ground voltage, a second PMOS transistor gated to a third node and connected between a second node and a second supply voltage having a second voltage level, a second NMOS transistor gated to the first node and connected between the second node and the ground voltage, a third PMOS transistor gated to the second node and connected between the second supply voltage and a third node, a third NMOS transistor gated to the input terminal and connected between the third node and the ground voltage, a fourth PMOS transistor gated to the second node and connected between the second supply voltage and a fourth node, a fifth PMOS transistor gated to the input terminal and connected between the fourth node and the output terminal, and a fourth NMOS transistor gated to the input terminal and connected between the output terminal and the ground voltage.

### BRIEF DESCRIPTION OF THE DRAWINGS

The above and other features and advantages of the present invention will become readily apparent from the detailed description that follows, with reference to the accompanying drawings, in which:

FIG. 1 is a circuit diagram of a conventional level shifter;

FIG. 2 is a circuit diagram of an interface circuit including a level shifter according to an embodiment of the present invention;

FIG. 3 is a circuit diagram of an interface circuit configured as a buffer-type level shifter according to another embodiment of the present invention; and

FIG. 4 is a circuit diagram of an interface circuit configured as an inverter-type level shifter according to another embodiment of the present invention.

### DETAILED DESCRIPTION OF PREFERRED EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their descriptions will not be repeated.

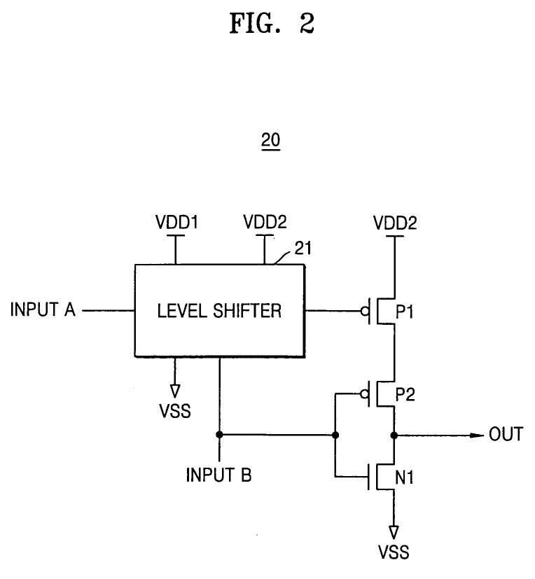

FIG. 2 is a circuit diagram of an interface circuit 20 including a level shifter 21 according to an embodiment of the present invention.

Referring to FIG. 2, the interface circuit 20 includes a level shifter 21, two PMOS transistors P1 and P2 connected to an output terminal of the level shifter 21, and a NMOS transistor N1.

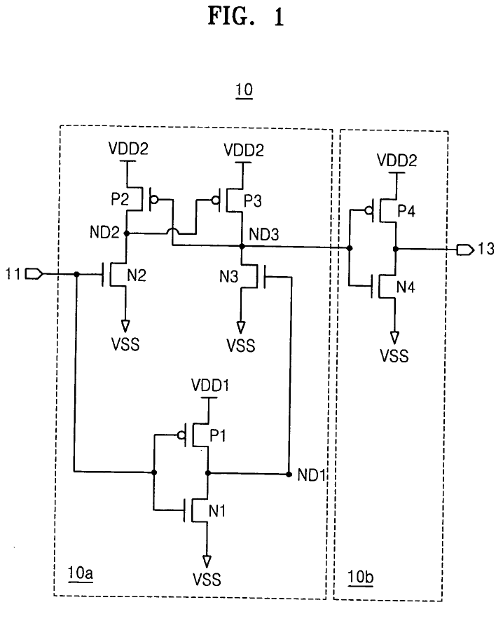

The level shifter 21 may generally be the same type as the conventional level shifter 10a shown and described previously in connection with FIG. 1.

FIG. 2 illustrates first and second input signals INPUT A and INPUT B. Typically, but not necessarily, these signals A and B will be inverted relative to each other. It should be understood, however, that a single input signal may be applied to the interface circuit 20. For example, in the case where the level shifter 21 is the same as the level shifter 10a of FIG. 1, the first and second input signals INPUT A and INPUT B correspond to signals appearing at the input terminal 11 and node ND1 of FIG. 1. In this case, the input signals INPUT A and INPUT B are derived from a single inputted signal.

The first and second input signals INPUT A and INPUT B have a first voltage level of VDD1. More specifically, when either input signal is logic HIGH, it has a voltage of VDD1, and when either signal is logic LOW, it has a voltage of VSS (ground).

The level shifter 21 receives the first and second input signals INPUT A and INPUT B and outputs a corresponding signal having a second voltage level VDD2. A first PMOS transistor P1, a second PMOS transistor P2, and a first NMOS transistor N1 are connected in series between the second supply voltage VDD2 and the ground voltage VSS. The output signal of the level shifter 21 is applied to the gate of the first PMOS transistor P1 and the second input signal INPUT B is applied to the gates of the second PMOS transistor P2 and the first NMOS transistor N1.

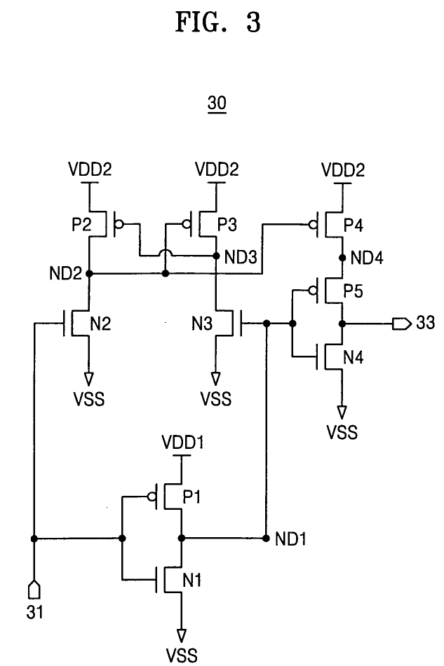

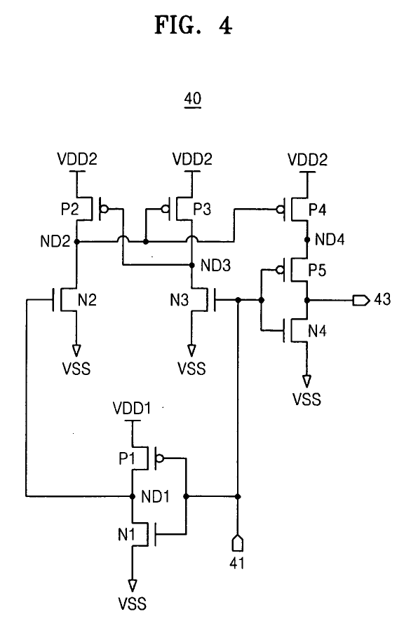

As will be explained in the examples given below (FIGS. 3 and 4), the interface circuit 20 of FIG. 2 may be configured as an inverter-type level shifter or a buffer-type level shifter.

In the interface circuit 20, the main path of signal propagation includes a single stage from the second input signal INPUT B to the second PMOS transistor P2 or to the first NMOS transistor N1. Accordingly, in the present embodiment, since the main path of signal propagation from an input terminal to an output terminal is shorter than in the conventional interface circuit 10 (FIG. 1), a delay time can be reduced.

In the meantime, in the case where the first supply voltage VDD1 is lower than the second supply voltage VDD2, the second PMOS transistor P2 may not sufficiently turned off by the second input signal INPUT B (VDD1). As such, to prevent leakage current in this situation, the embodiment is configured to turn off the first PMSO transistor P1 using the level shifter 21, thus blocking the leakage path through the second PMOS transistor P2.

FIG. 3 is a circuit diagram of an interface circuit 30 configured as a buffer-type level shifter according to an embodiment of the present invention.

The interface circuit 30 includes an input terminal 31 for receiving an input signal, an output terminal 33 for outputting an output signal, five PMOS transistors P1 through P5, and four NMOS transistors N1 through N4.

In FIG. 3, a first supply voltage VDD1 has a first voltage level and a second supply voltage VDD2 has a second voltage level. Here, the first voltage level may be higher or lower than the second voltage level. If the first voltage level is higher than the second voltage, the interface circuit 30 is a down-level shifter and if the first voltage level is lower than the second voltage level, the interface circuit 30 is an up-level shifter.

The first PMOS transistor P1 is connected between the first supply voltage VDD1 and a first node ND1. The gate of the first PMOS transistor P1 is connected to the input terminal 31. The first NMOS transistor N1 is connected between the first node ND1 and a ground voltage. The gate of the first NMOS transistor N1 is connected to the input terminal 31. The second PMOS transistor P2 is connected between the second supply voltage VDD2 and a second node ND2 and the gate of the second PMOS transistor P2 is connected to a third node ND3. The second NMOS transistor N2 is connected between the second node ND2 and the ground voltage and the gate of the second NMOS transistor N2 is connected to the input terminal 31. The third PMOS transistor P3 is connected between the second supply voltage VDD2 and the third node ND3 and the gate of the third PMOS transistor P3 is connected to the second node ND2. The fourth PMOS transistor P4 is connected between the second supply voltage VDD2 and a fourth node ND4 and the gate of the fourth PMOS transistor P4 is connected to the second node ND2.

The fifth PMOS transistor P5 is connected between the fourth node ND4 and the output terminal 33 and the gate of the fifth PMOS transistor P5 is connected to the first node ND1. The fourth NMOS transistor N4 is connected between the output terminal 33 and the ground voltage and the gate of the fourth NMOS transistor is connected to the first node ND1.

Hereinafter, the operation of the interface circuit 30 according to the present embodiment will be described with reference to FIG. 3.

If a logic HIGH signal of the first voltage level is applied to the input terminal 31, the first PMOS transistor P1 is turned off and the first NMOS transistor N1 is turned on, so that the output of a first node ND1 goes LOW. Accordingly, the second NMOS transistor N2 is turned on and the third NMOS transistor N3 is turned off, so that the output of the second node ND2 goes LOW and the output of the third node ND3 goes HIGH. At this time, the second PMOS transistor P2 is turned off so as to fix the output of the second node ND2 to LOW, and the third PMOS transistor P3 is turned on so as to fix the output of the third node ND3 to HIGH. When the output of the second node ND2 goes LOW, the fourth and fifth PMOS transistors P4 and P5 are turned on. When the output of the first node ND1 goes LOW, the fourth NMOS transistor N4 is turned off. Accordingly, the output of the output terminal 33 of the interface circuit 30 goes HIGH. The logic HIGH signal of the output terminal 33 has the second voltage level VDD2.

In this case, a delay time from when the logic HIGH signal is input to the input terminal 31 to when the output of the output terminal 33 rises simultaneously depends on two sets (or propagation directions) of two transistor stages. The first set of two transistor stages includes the second NMOS transistor N2 for transitioning the output of the second node ND2 to LOW and the fourth PMOS transistor P2 for transitioning the output of the fourth node ND4 to HIGH. The second set of two transistor stages includes the first NMOS transistor N1 for transitioning the output of the first node ND1 to LOW and the fifth PMOS transistor P5 and the fourth NMOS transistor N4 for transitioning the output of the output terminal 33 to HIGH.

Thus, in the case of a HIGH input signal, the main path of signal propagation from the input terminal 31 to the output terminal 33 in any one of the two propagation directions includes a maximum of two transistor stages. This represents a 50% reduction in delay time when compared to four transistor stages encountered in the buffer-type configuration employing the conventional interface device of FIG. 1.

If a logic LOW signal is applied to the input terminal 31, the first PMOS transistor P1 is turned on and the first NMOS transistor N1 is turned off, so that the output of the first node ND1 goes HIGH. Accordingly, the second NMOS transistor N2 is turned off and the third NMOS transistor N3 is turned on. Further, the output of the second node ND2 goes HIGH and the output of the third node ND3 goes LOW. At this time, the second PMOS transistor P2 is turned on so as to fix the output of the second node ND2 to HIGH, and the third PMOS transistor P3 is turned off so as to fix the output of the third node ND3 to LOW. The fourth PMOS transistor P4 is turned off when the output of the second node ND2 goes HIGH, and the fifth PMOS transistor P5 is turned off when the output of the first node ND1 goes HIGH. Further, the fourth NMOS transistor N4 is turned on when the output of the first node ND1 goes HIGH. Accordingly, the output of the output terminal 33 of the level shifter 30 goes LOW.

In this case, the delay time from when the logic LOW signal is input to the input terminal 31 to when the output of the output terminal 33 falls depends on two transistor stages, namely, the first PMOS and NMOS transistors P1 and N1 for transitioning the output of the first node ND1 to HIGH and the fourth NMOS transistor N4 for transitioning the output of the output terminal 33 to LOW.

Thus, in the case of a LOW input signal, the main path of signal propagation from the input terminal 31 to the output terminal 33 includes a maximum of two transistor stages. This represents a 50% reduction in delay time when compared to four transistor stages encountered in the buffer-type configuration employing the conventional interface device of FIG. 1.

The interface circuit 30 illustrated in FIG. 3 corresponds to the interface circuit 20 illustrated in FIG. 2 in the case where the first input signal INPUT A of FIG. 2 corresponds to a signal applied to the input terminal 31 of FIG. 3, and the output signal OUT of FIG. 2 corresponds to a signal output from the output terminal 33 of FIG. 3. The second input signal INPUT signal of FIG. 2 corresponds to the signal of the first node ND1 of FIG. 3. The level shifter 21 of FIG. 2 is composed of the first through third PMOS transistors P1 through P3 and the first through third NMOS transistors N1 through N3 of FIG. 3. Here, the first NMOS transistor N1 and the first PMOS transistor P1 invert the first input signal INPUT A and generate the second input signal INPUT B.

FIG. 4 is a circuit diagram of an interface circuit configured as an inverter-type level shifter according to another embodiment of the present invention.

The interface circuit 40 shown in FIG. 4 includes an input terminal 41 for receiving an input signal, an output terminal 43 for outputting an output signal, five PMOS transistors P1 through P5, and four NMOS transistors N1 through N4.

A first supply voltage VDD1 has a first voltage level and a second supply voltage VDD2 has a second voltage level. Here, the first voltage level may be higher or lower than the second voltage level. If the first voltage level is higher than the second voltage, the interface circuit 40 operates as a down-level shifter, and if the first voltage level is lower than the second voltage level, the interface circuit 40 operates as an up-level shifter.

The first PMOS transistor P1 is connected between the first supply voltage VDD1 and a first node ND1 and the gate of the first PMOS transistor P1 is connected to the input terminal 41. The first NMOS transistor N1 is connected between the first node ND1 and a ground voltage and the gate of the first NMOS transistor N1 is connected to the input terminal 41. The second PMOS transistor P2 is connected between the second supply voltage VDD2 and a second node ND2 and the gate of the second PMOS transistor P2 is connected to a third node ND3. The second NMOS transistor N2 is connected between the second node ND2 and the ground voltage and the gate of the second NMOS transistor N2 is connected to the first node ND1. The third PMOS transistor P3 is connected between the second supply voltage VDD2 and the third node ND3 and the gate of the third PMOS transistor P3 is connected to the second node ND2. The third NMOS transistor N3 is connected between the third node ND3 and the ground voltage and the gate of the third NMOS transistor N3 is connected to the input terminal 41. The fourth NMOS transistor N4 is connected between the second supply voltage VDD2 and a fourth node ND4 and the gate of the fourth NMOS transistor N4 is connected to the second node ND2. The fifth PMOS transistor P5 is connected between the fourth node ND4 and the output terminal 43 and the gate of the fifth PMOS transistor P5 is connected to the input terminal 41. The fourth NMOS transistor N4 is connected between the output terminal 43 and the ground voltage and the gate of the fourth NMOS transistor N4 is connected to the input terminal 43.

Hereinafter, the operation of the interface circuit 40 according to the present embodiment will be described with reference to FIG. 4.

If a logic HIGH signal with the first voltage level is applied to the input terminal 41, the first PMOS transistor P1 is turned off and the first NMOS transistor N1 is turned on, so that the output of the first node ND1 goes LOW. Also, the fourth NMOS transistor N4 is turned on in response to the signal of the input terminal 41. Accordingly, the voltage of the output terminal 43 goes LOW. Since the output of the input terminal 41 is HIGH and the output of the first node ND1 is LOW, the second NMOS transistor N2 is turned off and the third NMOS transistor N3 is turned on. Accordingly, the output of the second node ND2 goes HIGH and the output of the third node ND3 goes LOW. At this time, the second PMOS transistor P2 is turned on so as to fix the output of the second node ND2 to HIGH, and the third PMOS transistor P3 is turned off so as to fix the output of the third node ND3 to LOW. The fourth PMOS transistor P4 is turned off when the output of the second node ND2 goes HIGH. Meanwhile, the fifth PMOS transistor P5 cannot be directly turned off when the first voltage level VDD1 of the input terminal 41 received through the gate is lower than the second voltage level VDD2. However, even when the fifth PMOS transistor P5 is turned off, the fourth PMOS transistor P4 is turned off and the fourth NMOS transistor N4 is turned on, so that the voltage of the output terminal 33 goes LOW.

In this case, a delay time from when the logic HIGH signal is input to the input terminal 41 to when the output of the output terminal falls depends on a single stage of the fourth NMOS transistor N4, since the signal is directly transmitted from the input terminal 41 to the output terminal 43 through the fourth NMOS transistor N4. Accordingly, this signal delay time of the interface circuit 40 is substantially less than that of the conventional interface circuit 10 illustrated in FIG. 1.

If a logic LOW signal is applied to the input terminal 41, the first PMOS transistor P1 is turned on and the first NMOS transistor N1 is turned off, so that the output of the first node ND1 goes HIGH. Also, the fourth NMOS transistor N4 is turned off and the fifth PMOS transistor P5 is turned on in response to the signal of the input terminal 41. Since the output of the input terminal 41 is LOW and the output of the first node ND1 is HIGH, the second NMOS transistor N2 is turned on and the third NMOS transistor N3 is turned off. Also, the output of the second node ND2 goes LOW and the output of the third node ND3 goes HIGH. At this time, the second PMOS transistor P2 is turned off so as to fix the output of the second node ND2 to LOW, and the third PMOS transistor P3 is turned on so as to fix the output of the third node ND3 to HIGH. The fourth PMOS transistor P4 is turned on when the output of the second node ND2 goes LOW. As described above, since the fifth PMOS transistor P5 is turned on and the fourth NMOS transistor N4 is turned off, the voltage of the output terminal 43 goes HIGH.

In this case, a delay time from when the logic LOW signal is input to the input terminal 41 to when the output of the output terminal 43 rises, depends on three stage, namely, the first NMOS transistor N1 for transitioning the output of the first node ND1 to HIGH, the second NMOS transistor N2 for transitioning the output of the second NMOS transistor N2 to LOW, and the fourth PMOS transistor P4 for transitioning the output of the output terminal 43 to HIGH. That is, a rise timing of the output signal of the output terminal 43 is delayed until the fourth PMOS transistor P4 is turned on since a signal is not directly transmitted from the input terminal 41 to the output terminal 43 through the fourth NMOS transistor N4. The reason for this is because although the fifth PMOS transistor P5 is turned on and the fourth NMOS transistor N4 is turned off, the second supply voltage VDD2 is transmitted to the output terminal 43 when the fourth PMOS transistor P4 is turned on. Accordingly, since the main path of signal propagation when the output of the output terminal 43 rises, includes total three stages of the first NMOS transistor N1, the second NMOS transistor N2, and the fourth PMOS transistor P4, thus the delay time also depends on the three stages.

The interface circuit 40 illustrated in FIG. 4 corresponds to the interface circuit 20 illustrated in FIG. 2 in the case where the first and second input signals INPUT A and INPUT B of FIG. 2 correspond to signals applied to the input terminal 41 of FIG. 4. Also in this case, the level shifter 21 illustrated in FIG. 2 includes the first through third PMOS transistors P1 through P3 and the first through third NMOS transistors N1 through N3, as shown in FIG. 4. Here, the first NMOS and PMOS transistors N1 and P1 respectively invert the first and second input signals INPUT A and INPUT B, and output the inverted results to the first node ND1.

It is noted that one modification of the interface circuits 30 and 40 of FIGS. 3 and 4, respectively, is to add an inverter at the input terminal or output terminal of the interface circuits.

According to the level shifter of embodiments of the present invention, it is possible to minimize a delay time without any increase in the interface area between circuit blocks using different voltage levels and efficiently varying voltage levels. Although the invention is not so limited, the embodiments may be particularly useful in low-power mobile devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An interface circuit, comprising:
a level shifter which shifts a voltage level of a first signal and a second signal from a first voltage level to a second voltage level;
a first PMOS transistor gated to an output of the level shifter and connected between a first node and a supply voltage of the second voltage level;
a second PMOS transistor gated to receive a second signal and connected between the first node and an output terminal; and
a first NMOS transistor gated to receive the second signal and connected between the output terminal and a ground voltage.

2. The interface circuit of claim 1, wherein at least one of the first and second signals is an input signal.

3. The interface circuit of claim 1, wherein the first signal is inverted relative to the second signal.

4. The interface circuit of claim 1, wherein the first voltage level is lower than the second voltage level.

5. The interface circuit of claim 1, wherein the first voltage level is higher than the second voltage level.

6. An interface circuit, comprising:
an input terminal which receives an input signal;
an output terminal which outputs an output signal;
a first PMOS transistor gated to the input terminal and connected between a first node and a first supply voltage having a first voltage level;
a first NMOS transistor gated to the input terminal and connected between the first node and a ground voltage;
a second PMOS transistor gated to a third node and connected between a second node and a second supply voltage having a second voltage level;
a second NMOS transistor gated to the input terminal and connected between the second node and the ground voltage;
a third PMOS transistor gated to the second node and connected between the second supply voltage and a third node;
a third NMOS transistor gated to the first node and connected between the third node and the ground voltage;
a fourth PMOS transistor gated to the second node and connected between the second supply voltage and a fourth node;
a fifth PMOS transistor gated to the first node and connected between the fourth node and the output terminal; and
a fourth NMOS transistor gated to the first node and connected between the output terminal and the ground voltage.

7. The interface circuit of claim 6, further comprising an inverter connected to the output terminal and inverting the output signal of the output terminal.

8. The interface circuit of claim 6, wherein the first voltage level is lower than the second voltage level.

9. The interface circuit of claim 6, wherein the first voltage level is higher than the second voltage level.

10. An interface circuit, comprising:
an input terminal which receives an input signal;
an output terminal which outputs an output signal;
a first PMOS transistor gated to the input terminal and connected between a first node and a first supply voltage having a first voltage level;
a first NMOS transistor gated to the input terminal and connected between the first node and a ground voltage;
a second PMOS transistor gated to a third node and connected between a second node and a second supply voltage having a second voltage level;
a second NMOS transistor gated to the first node and connected between the second node and the ground voltage;
a third PMOS transistor gated to the second node and connected between the second supply voltage and a third node;
a third NMOS transistor gated to the input terminal and connected between the third node and the ground voltage;
a fourth PMOS transistor gated to the second node and connected between the second supply voltage and a fourth node;
a fifth PMOS transistor gated to the input terminal and connected between the fourth node and the output terminal; and
a fourth NMOS transistor gated to the input terminal and connected between the output terminal and the ground voltage.

11. The interface circuit of claim 10, further comprising an inverter connected to the output terminal and inverting the output signal of the output terminal.

12. The interface circuit of claim 10, wherein the first voltage level is lower than the second voltage level.

13. The interface circuit of claim 10, wherein the first voltage level is higher than the second voltage level.
